(19) United States
(12) Patent Application Publication
(10) Pub. No.: US 2017/0279115 A1
(43) Pub. Date: Sep. 28, 2017

(54) SPECIAL LiPON MASK TO INCREASE LiPON IONIC CONDUCTIVITY AND TFB FABRICATION YIELD

(71) Applicant: APPLIED MATERIALS, INC., Santa Clara, CA (US)

(72) Inventors: Daoying SONG, San Jose, CA (US); Chong JIANG, Cupertino, CA (US); Lizhong SUN, San Jose, CA (US); Byung Sung Leo KWAK, Portland, OR (US)

(21) Appl. No.: 15/505,864

(22) PCT Filed: Aug. 28, 2015
(86) PCT No.: PCT/US2015/047413

§ 371 Date: Feb. 22, 2017

Related U.S. Application Data
(60) Provisional application No. 62/042,943, filed on Aug. 28, 2014.

(51) Int. Cl. H01M 4/1391; H01M 4/04; C23C 14/06; H01M 10/0562; H01M 10/0585; H01M 4/525; H01M 10/0525

(52) U.S. Cl. CPC H01M 4/1391; H01M 4/525; H01M 4/0426; H01M 10/0525; H01M 10/0562; H01M 10/0585; C23C 14/06

(57) ABSTRACT

According to general aspects, embodiments of the present disclosure relate to a special mask design that not only increases the ionic conductivity of a deposited LiPON layer but also increases device yield by reducing damage to the deposited layer from RF plasma. In embodiments, the mask includes a conductive bottom surface facing the substrate during deposition and a non-conductive opposite top side. According to aspects of the present disclosure, the conductive portion of the mask at the bottom side allows the formation of a weak secondary local plasma (or greater plasma immersion) to enhance nitrogen incorporation into the LiPON film. The non-conductive top side suppresses local micro-arcing, which will limit the plasma induced damage to the growing film.

### CROSS-REFERENCE TO RELATED APPLICATIONS

This application claims the benefit of U.S. Provisional Application No, 62/042,943, filed Aug. 28, 2014.

### FIELD

In general, embodiments of the present disclosure relate to special mask design for LiPON electrolyte layer and thin film battery (TFB) manufacturing,

### BACKGROUND

Thin film batteries (TFB), with their unsurpassed properties, have been projected to dominate the μ-energy application space for the foreseeable future. The TFB electrolyte, typically comprised of LiPON, is important for Li diffusion rate during charge/discharge process wherein the electrolyte layer affects the battery performance in general including the cycling performance and rate capability. In addition, a high quality LiPON layer without, or with less, pinholes or damages is one of the top factors for improving TFB yield.

Clearly, there is a need for apparatuses and methods of manufacture that effectively increase battery performance and TFB manufacturing yield by improving electrolyte layer characteristics and reducing damages thereto during processing.

### SUMMARY

According to general aspects, embodiments of the present disclosure relate to a special mask design that not only increases the ionic conductivity of a deposited LiPON layer but also increases device yield by reducing damages to the layer from RF (radio frequency) plasma. In embodiments, the mask includes an electrically conductive bottom film facing side and an electrically non-conductive opposite top side. According to aspects of the present disclosure, the conductive portion of the mask at the bottom side allows the formation of a weak secondary local plasma (or greater plasma immersion) to enhance nitrogen incorporation into the LiPON film. The non-conductive top side suppresses local micro-arcing, which will limit the plasma induced damage to the growing film.

According to some embodiments, a method of manufacturing electrochemical devices may comprise: providing a mask having top and bottom sides, said bottom side being electrically conductive and said top side being electrically non-conductive; forming a stack of device layers on a substrate, said stack of device layers comprising: a current collector layer on said substrate; and an electrode layer on said current collector layer; arranging said mask with said bottom side adjacent to a top surface of said stack; and depositing an electrolyte layer on said stack using a PVD process with said mask arranged having said bottom side adjacent to said film stack.

According to some embodiments, a system for manufacturing electrochemical devices may comprise: a shadow mask for patterning an electrolyte layer of an electrochemical device, said shadow mask comprising: a planar body with top and bottom sides, said bottom side having an electrical conductivity in the range of 10⁵ to 10⁷ S/m and said top side having an electrical conductivity less than 10⁻⁷ S/m; and a first system for depositing a device stack on a substrate comprising a current collector, an electrode layer, and said electrolyte layer, said first system comprising a PVD deposition tool configured for depositing said electrolyte with said shadow mask with said bottom side of said shadow mask facing said substrate during said depositing.

According to some embodiments, a shadow mask for patterning an electrolyte layer of an electrochemical device may comprise: a planar body with a top side and a bottom side, said bottom side having an electrical conductivity in the range of 10⁵ to 10⁷ S/m and said top side having an electrical conductivity less than 10⁻⁷ S/m.

### BRIEF DESCRIPTION OF THE DRAWINGS

These and other aspects and features of the present disclosure will become apparent to those ordinarily skilled in the art upon review of the following description of specific embodiments of the disclosure in conjunction with the accompanying figures, wherein:

FIG. 1 shows a cross-sectional representation of a completed structure of a thin film battery (TFB) according to embodiments;

FIG. 2 is a cross-sectional diagram illustrating aspects of an apparatus and method of manufacture according to embodiments of the present disclosure;

FIG. 3 is a plot illustrating a voltage vs. capacity discharge curve of a TFB fabricated using a mask according to embodiments of the present disclosure;

FIG. 4 is a schematic illustration of a processing system 400 for fabricating a TFB, according to some embodiments;

FIG. 5 shows a representation of an in-line fabrication system with multiple in-line tools, according to some embodiments; and

FIG. 6 illustrates the movement of a substrate through an in-line fabrication system such as shown in FIG. 5, according to some embodiments.

### DETAILED DESCRIPTION

Embodiments of the present disclosure will now be described in detail with reference to the drawings, which are provided as illustrative examples of the disclosure so as to enable those skilled in the art to practice the disclosure. Notably, the figures and examples below are not meant to limit the scope of the present disclosure to a single embodiment, but other embodiments are possible by way of interchange of some or all of the described or illustrated elements. Moreover, where certain elements of the present disclosure can be partially or fully implemented using known components, only those portions of such known components that are necessary for an understanding of the present disclosure will be described, and detailed descriptions of other portions of such known components will be omitted so as not to obscure the disclosure. In the present specification, an embodiment showing a singular component should not be considered limiting; rather, the disclosure is intended to encompass other embodiments including a plurality of the same component, and vice-versa, unless explicitly stated otherwise herein. Moreover, applicants do not intend for any term in the specification or claims to be ascribed an uncommon or special meaning unless explicitly set forth as such. Further, the present disclosure encompasses present and future known equivalents to the known components referred to herein by way of illustration.

Electrochemical devices such as thin film batteries (TFBs) and electrochromic devices (EC) include a thin film stack of layers including current collectors, a cathode (positive electrode), a solid state electrolyte and an anode (negative electrode).

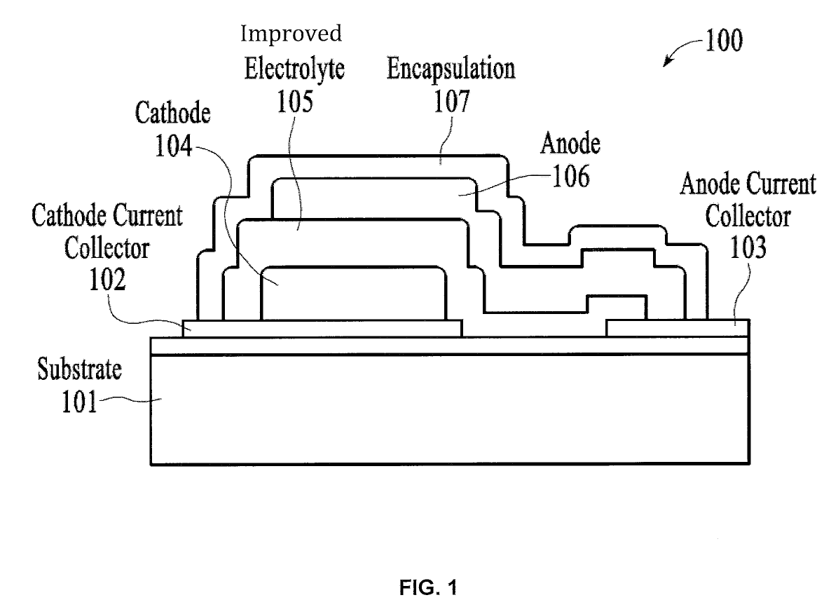

FIG. 1 shows a cross-sectional representation of a typical thin film battery (TFB) structure 100 with cathode current collector 102 and anode current collector 103 formed on a substrate 101, followed by a cathode layer 104, an improved electrolyte layer 105 (fabricated according to methods of the present disclosure) and anode layer 106; although the device may be fabricated with the cathode, electrolyte and anode in reverse order. Furthermore, the cathode current collector (CCC) and anode current collector (ACC) may be deposited separately. For example, the CCC may be deposited before the cathode and the ACC may be deposited after the electrolyte. The device may be covered by an encapsulation layer 107 to protect the environmentally sensitive layers from oxidizing agents. Note that the component layers are not drawn to scale in the TFB device shown in FIG. 1. Furthermore, an example of a cathode layer 104 is a LiCoO₂ (LCO) layer (deposited by e.g. RF sputtering, pulsed DC sputtering, etc.), of an improved electrolyte layer 105 is a LiPON layer (deposited by e.g. RF sputtering, etc. and using masks and methods according to embodiments of the present disclosure) and of an anode layer 106 is a Li metal layer (deposited by e.g. evaporation, sputtering, etc.).

In conventional TFB manufacturing, all of the layers shown in FIG. 1 are patterned using in-situ shadow masks which are fixed to the device substrate 101 by backside magnets or sub-carriers or Kapton® tape. Typically, masks comprised of a single material, either metal or ceramic, are used. However, the authors of the present disclosure discovered that during formation of an electrolyte layer 105 using masks made of metal only, the LiPON layer tends to be damaged by RF plasma—for example, the LiPON layer may incur micro-arcing induced damage primarily along the edges of the open and pattern areas of the mask resulting in defects such as micro-burns, pinholes, surface roughness and dendrites. On the other hand, using masks made of ceramic materials only, the ionic conductivity of the UPON layer was found to be significantly reduced compared to using metal masks.

According to certain general aspects, therefore, embodiments of an apparatus and method of manufacture according to the present disclosure not only increase the ionic conductivity of an electrolyte layer comprising LiPON, but also increase TFB device manufacturing yield by reducing damages to the electrolyte layer from RF plasma.

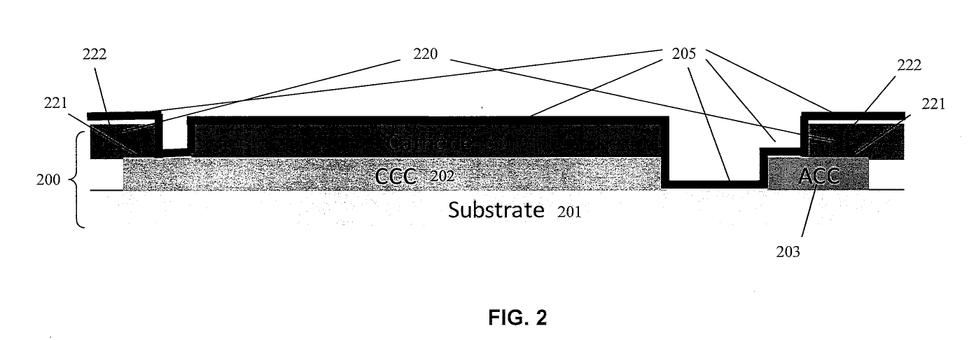

FIG. 2 illustrates aspects of an apparatus and method of manufacture according to embodiments of the present disclosure.

More particularly, FIG. 2 is a cross-sectional diagram that illustrates a TFB stack 200 at an electrolyte layer formation stage. As shown, film stack 200 under process includes a substrate 201, a deposited and patterned cathode current collector 202, a deposited and patterned anode current collector 203 and a deposited and patterned cathode 204. FIG. 2 further illustrates an electrolyte layer 205 during the process of being deposited. According to aspects of the disclosure, during deposition of the electrolyte (e.g. LiPON) layer, a shadow mask 220 according to embodiments is used. Mask 220 is arranged such that it has a bottom side 221 touching the deposited current collector layers 202 and 203 surfaces (i.e. before electrolyte layer deposition and after patterning of the deposited cathode layer 204) and a top/front side 222.

In accordance with aspects of this disclosure, sides 221 and 222 of mask 220 may have very different electrical conductivities. In a preferred embodiment, side 221 is electrically conductive and side 222 is electrically non-conductive. As used herein, the term “electrically conductive” refers to a material that has electrical conductivity in a range of 10⁵ to 10⁷ S/m and preferably greater than 10⁶ S/m (or in a range of 10⁶ to 10⁷ S/m). As further used herein, the term “electrically non-conductive” refers to a material that has electrical conductivity less than 10⁻⁷ S/m and preferably less than 10⁻¹⁰ S/m.

Preparing a mask 220 having very different conductivities on sides 221 and 222 can be implemented in many various ways. In embodiments, mask 220 can be formed substantially with a single material that also forms one of sides 221 and 222, with the other side formed by coating or treating the material. For example, mask 220 can be a stainless steel or invar base material that forms side 221 coated with a dielectric layer such as silicon dioxide and silicon nitride on top to form side 222. Another example is a mask 220 can be substantially comprised of the same types of metal as in the previous example to form side 221 with surface oxidation performed to form side 222. In other embodiments, sides 221 and 222 can both be formed by coating or treating a different material that substantially forms mask 220. In still other embodiments, sides 221 and 222 can be different materials that are bonded together to form mask 220.

One non-limiting example of process conditions for depositing a LiPON electrolyte layer on a cathode layer comprising LiCoO₂ (e.g. about 10μm thick) using a shadow mask 220 such as that shown in FIG. 2 according to embodiments is as follows: a Li₃PO₄ target, RF sputtering in N₂ gas at a frequency of about 2 MHz to about 80 MHz, power of about 500W to about 3000W, temperature of about room temperature to 200° C. for about 1 to 6 hours. In such an example, shadow mask 220 is stainless steel or Invar about 200 μm thick with a dielectric coating (e.g. 1 μm silicon dioxide) to form non-conductive side 222.

Although the disclosure has been provided above in connection with LiPON deposited on a LiCoO₂ layer, alternative embodiments can include more reactive RF sputtering of electrolyte in which more elements from the gas plasma are incorporated into the deposited film.

The authors of the present disclosure discovered an advantageous effect that ionic conductivity of the LiPON electrolyte layer is significantly increased by arranging the mask 220 such that the film stack directly contacts the conductive surface 221 during LiPON deposition performed as described above. Given the fact that all deposition situations (i.e., target material, sputtering conditions, sputtering ambient, and all other hardware and process), except the mask configuration, are the same, the present authors deduce that higher ionic conductivity is likely caused by the greater incorporation of nitrogen into the depositing LiPON layer. Such greater nitrogen-incorporation may likely originate from a secondary local plasma formation between the conductive mask surface and the top of conductive LiCoO₂ or current collector layers. This secondary plasma will create additional N⁺ species in the local area for increased incorporation. Another possibility is that the conductive metal inducing greater “attraction” to the sputtering plasma above and causing an “expansion of the plasma volume,” which would lead to a greater “immersion” of the growing films to the plasma and its contents (N⁺ ions) and to the greater nitrogen incorporation. Yet another possibility is the bias equilibration between the CCC and the mask, through the underside of the mask 221 that creates greater and more uniform negative bias to better and more uniformly attract nitrogen ions from the plasma for bombardment of the LiPON layer and incorporation therein.

The authors of the present disclosure have further observed damage to the LiPON layer when a fully conductive mask (e.g. all metal) is used during LiPON deposition, especially in the case of a thick cathode (e.g. >10 μm). The damage may be due to local micro-arcing between the exposed conductive mask and the top of the conductive LiCoO₂ and current collector layers (with the formation of the aforementioned secondary plasma or with the greater plasma immersion, or the local differential bias without a good equilibration method).

This type of damage is advantageously reduced when using the mask 220 of the present disclosure. Furthermore, there is less RF plasma damage on LiPON films resulting in a high quality LiPON layer and high quality TFB device and yield.

Table 1 below provides a comparison of measured ionic conductivity of a LiPON layer deposited with various configurations of a shadow mask. As shown in Table 1 below, by using a mask 220 having a conductive bottom side 221 and non-conductive top side 222, the ionic conductivity has been increased from 1.2 to 2.8 μS/cm at a certain LiPON deposition condition when compared with a mask with non-conductive bottom side and conductive top side (and it is expected that a similar comparison would be seen between the masks of configurations 1 and 4), and thick cathode (e.g. >10 μm) TFBs are also successfully fabricated with excellent charge/discharge performance. In the example below, LiPON condition 1 refers to RF power of 1750W, N₂ pressure of 5 mTorr and substrate heater temperature of 100° C. and LiPON condition 2 refers to RF power of 2200W, N₂ pressure of 5 mTorr, and substrate heater temperature of 100° C. Both conditions were performed in a PVD (physical vapor deposition) chamber.

Using masks of the present disclosure—with conductive bottom side and non-conductive top side—it is seen that the advantageous higher ionic conductivity of the deposited LiPON (associated with metal masks) and less arcing damage in the deposited LiPON (associated with ceramic masks) can both be achieved.

TABLE 1

| | | | LiPON | LiPON |
|---|---|---|---|---|
| Configuration | Mask Top Side | Mask Bottom Side | Condition 1 | Condition 2 |
| 1 | Non-conductive | Conductive | 2.0 μS/cm | 2.8 μS/cm |
| 2 | Conductive | Conductive | Expect similar | 2.8 μS/cm |
| | | | result to that for | |
| | | | configuration 1. | |
| 3 | Conductive | Non-conductive | 1.4 μS/cm | 1.2 μS/cm |
| 4 | Non-conductive | Non-conductive | Expect similar | Expect similar |
| | | | result to that for | result to that for |
| | | | configuration 3. | configuration 3. |

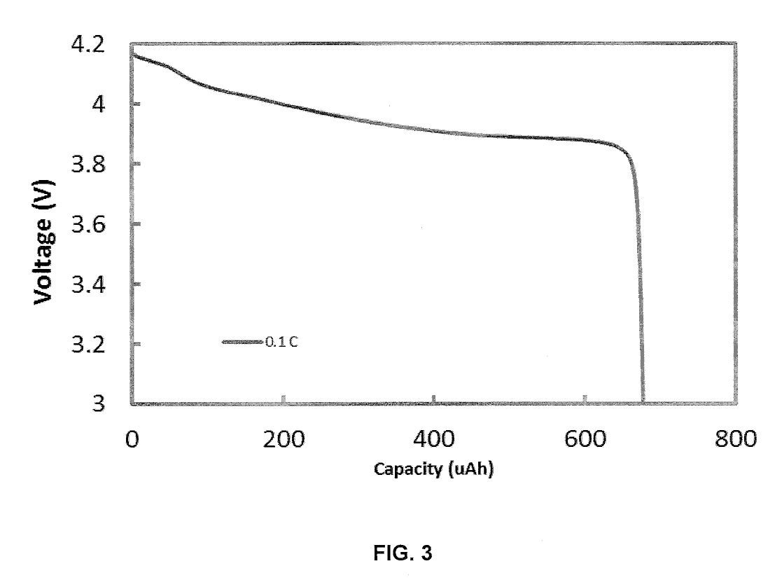

FIG. 3 is a plot illustrating a voltage vs. capacity discharge curve of a TFB fabricated using a mask 220 during LiPON deposition as described above. In this example, the fabricated TFB includes a 14.7 μm thick LCO cathode layer, 2.5 μm thick LiPON electrolyte layer, a 5 μm thick Li anode layer, a cell area of 1 cm² and a theoretical capacity of about 1014 μAh. Note that the thickness measurements may have about a +5% error. As seen in FIG. 3, the discharge curve shows the major flat potential plateau at 3.9 eV and two minor additional plateaus at 4.1 and 4.18 eV, which are the typical discharge characteristics of LiCoO₂.

Although not shown in FIG. 3, it should be noted that TFB devices fabricated according to embodiments exhibit relatively high capacity utilization (actual vs. theoretical) of about 70%. When materials density is accounted for (about 80 to 85%), utilization is even higher, indicating that the capacity utilization based on material content is very high, which implies that the improved LiPON material leads to better device performance. Still further, mask configurations according to embodiments are expected to enable higher device yields.

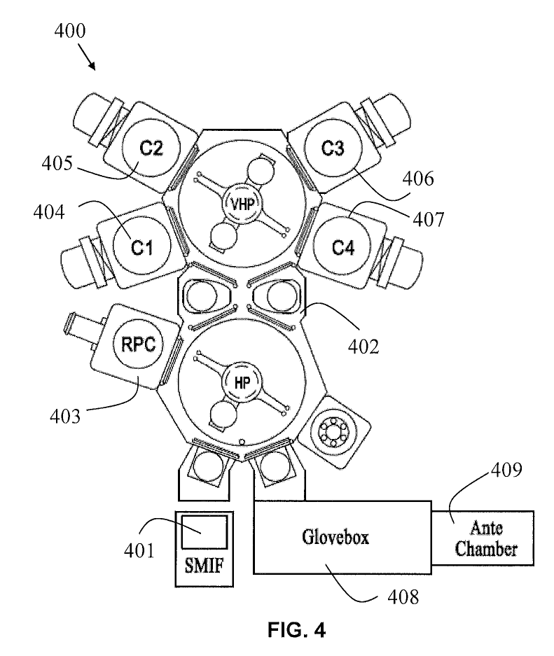

FIG. 4 is a schematic illustration of a processing system 400 for fabricating an electrochemical device, such as a TFB or EC device, according to some embodiments. The processing system 400 includes a standard mechanical interface (SMIF) 401 to a cluster tool 402 equipped with a reactive plasma clean (RPC) chamber 403 and process chambers C1-C4 (404, 405, 406 and 407), which may be utilized in the process steps described above. A glovebox 408 may also be attached to the cluster tool. The glovebox can store substrates in an inert environment (for example, under a noble gas such as He, Ne or Ar), which is useful after alkali metal/alkaline earth metal deposition. An ante chamber 409 to the glovebox may also be used if needed—the ante chamber is a gas exchange chamber (inert gas to air and vice versa) which allows substrates to be transferred in and out of the glovebox without contaminating the inert environment in the glovebox. (Note that a glovebox can be replaced with a dry room ambient of sufficiently low dew point as such is used by lithium foil manufacturers.) The chambers C1-C4 can be configured for process steps for manufacturing TFBs which may include, for example: deposition of a cathode layer (e.g. LiCoO₂ by RF sputtering); deposition of an electrolyte layer (e.g. Li₃PO₄ by RF sputtering in N₂); deposition of an alkali metal or alkaline earth metal; and patterning of layers using in-situ masks as described above. Examples of suitable cluster tool platforms include display cluster tools. It is to be understood that while a cluster arrangement has been shown for the processing system 400, a linear system may be utilized in which the processing chambers are arranged in a line without a transfer chamber so that the substrate continuously moves from one chamber to the next chamber.

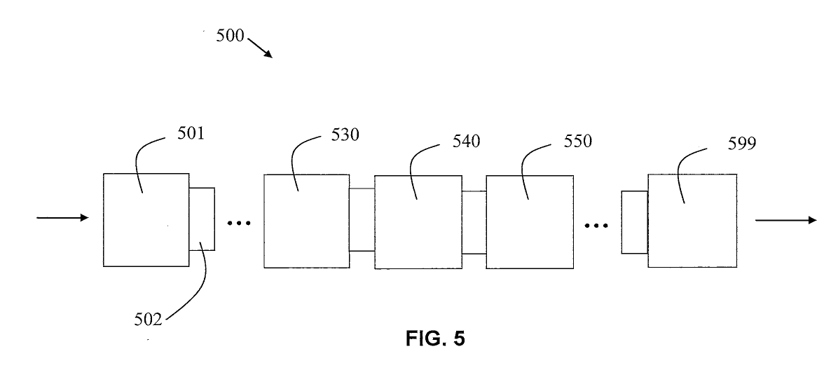

FIG. 5 shows a representation of an in-line fabrication system 500 with multiple in-line tools 501 through 599, including tools 530, 540, 550, according to some embodiments. In-line tools may include tools for depositing all the layers of a TFB. Furthermore, the in-line tools may include pre- and post-conditioning chambers. For example, tool 501 may be a pump down chamber for establishing a vacuum prior to the substrate moving through a vacuum airlock 502 into a deposition tool. Some or all of the in-line tools may be vacuum tools separated by vacuum airlocks. Note that the order of process tools and specific process tools in the process line will be determined by the particular TFB fabrication method being used, for example, as specified in the process flows described above. Furthermore, substrates may be moved through the in-line fabrication system oriented either horizontally or vertically.

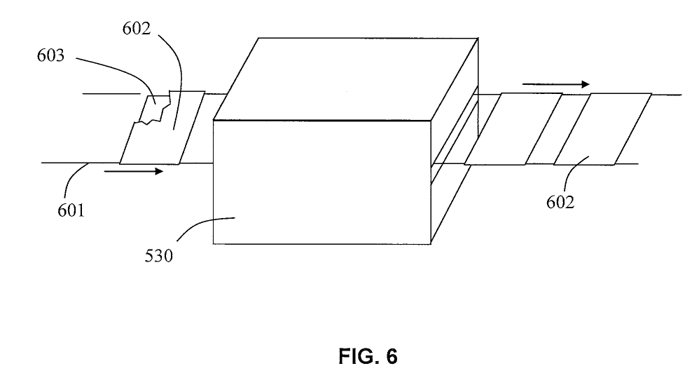

In order to illustrate the movement of a substrate through an in-line fabrication system such as shown in FIG. 5, in FIG. 6 a substrate conveyer 601 is shown with only one in-line tool 530 in place. A substrate holder 602 containing a substrate 603 (the substrate holder is shown partially cut-away so that the substrate can be seen) is mounted on the conveyer 601, or equivalent device, for moving the holder and substrate through the in-line tool 530, as indicated. Furthermore, substrates may be moved through the in-line fabrication system oriented either horizontally or vertically.

According to some embodiments, a system for manufacturing electrochemical devices may comprise: a shadow mask for patterning an electrolyte layer of an electrochemical device, said shadow mask comprising: a planar body with top and bottom sides, said bottom side having an electrical conductivity in the range of 10⁵ to 10⁷ S/m and said top side having an electrical conductivity less than 10⁻⁷ S/m; and a first system for depositing a device stack on a substrate comprising current collectors, electrode layers, and said electrolyte layer, said first system comprising a PVD deposition tool configured for depositing said electrolyte layer with said shadow mask with said bottom side of said shadow mask facing said substrate during said depositing. Furthermore, said first system may be configured for depositing further device layers such as an encapsulation layer, etc. In embodiments, the electrochemical device is a device such as shown in FIG. 1. The system may be a cluster tool, an in-line tool, stand-alone tools, or a combination of one or more of the aforesaid tools. In embodiments, the bottom side has an electrical conductivity in the range of 10⁶ to 10⁷ S/m. In embodiments, the top side has an electrical conductivity less than 10⁻¹⁰ S/m. In embodiments, the PVD deposition tool is an RF sputter deposition tool.

According to some embodiments, a method of manufacturing electrochemical devices may comprise: providing a mask having top and bottom sides, the bottom side being electrically conductive and the top side being electrically non-conductive; forming a stack of device layers on a substrate, the stack of device layers comprising: a current collector layer on the substrate, and an electrode layer on the current collector layer; arranging the mask with the bottom side adjacent to a top surface of the stack; and depositing an electrolyte layer on the stack using a PVD process with the mask arranged having the bottom side adjacent to the film stack. The method may further comprise, after the deposition of the electrolyte layer and the removal of the mask, depositing a second electrode layer over the electrolyte layer, and a second current collector over the second electrode layer. In embodiments, the mask is a shadow mask. In embodiments, the PVD process comprises RF sputtering. In embodiments, the bottom side has an electrical conductivity in the range of 10⁵ to 10⁷ S/m. In embodiments, the top side has an electrical conductivity less than 10⁻⁷ S/m. In embodiments, the bottom side has an electrical conductivity in the range of 10⁶ to 10⁷ S/m. In embodiments, the top side has an electrical conductivity less than 10⁻¹⁰ S/m.

According to some embodiments, a method of manufacturing electrochemical devices may comprise: providing a mask having top and bottom sides, the bottom side being electrically conductive and the top side being electrically non-conductive; forming a first stack of patterned device layers on a substrate, the first stack of patterned device layers comprising: first and second current collectors on the substrate, and a first electrode on the first current collector; arranging the mask with the bottom side adjacent to a top surface of the first stack; and depositing an electrolyte layer on the first stack to form a second stack, the depositing using a PVD process with the mask arranged having the bottom side adjacent to the first stack. The method may further comprise, after the deposition of the electrolyte and the removal of the mask, forming a patterned second electrode on the second stack to form a third stack. The method may yet further comprise, forming a patterned encapsulation layer on the third stack. In embodiments, the current collectors, the first electrode, the electrolyte, the second electrode layer and the encapsulation layer are configured as the TFB of FIG. 1. In embodiments, the first and second electrodes are anode and cathode, respectively. In further embodiments, the first and second electrodes are cathode and anode, respectively. In embodiments, the mask is a shadow mask. In embodiments, the PVD process comprises RF sputtering. In embodiments, the bottom side has an electrical conductivity in the range of 10⁵ to 10⁷ S/m. In embodiments, the top side has an electrical conductivity less than 10⁻⁷ S/m. In embodiments, the bottom side has an electrical conductivity in the range of 10⁶ to 10⁷ S/m. In embodiments, the top side has an electrical conductivity less than 10⁻¹⁰ S/m.

Although embodiments of the present disclosure have been particularly described with reference to lithium ion electrochemical devices, the teaching and principles of the present disclosure may also be applied to electrochemical devices based on transport of other ions, such as protons, sodium ions, etc.

Although embodiments of the present disclosure have been particularly described with reference to TFB devices, the teaching and principles of the present disclosure may also be applied to various electrochemical devices including electrochromic devices, electrochemical sensors, electrochemical capacitors and devices in which an electrolyte layer is sputter deposited with a shadow mask.

Although the present disclosure has been particularly described with reference to certain embodiments, it should be readily apparent to those of ordinary skill in the art that changes and modifications in the form and details may be made without departing from the spirit and scope of the disclosure. It is intended that the present disclosure encompasses such changes and modifications.

What is claimed is:

1. A method of manufacturing electrochemical devices comprising:
providing a mask having top and bottom sides, said bottom side being electrically conductive and said top side being electrically non-conductive;
forming a stack of device layers on a substrate, said stack of device layers comprising:
a current collector layer on said substrate; and
an electrode layer on said current collector layer;
arranging said mask with said bottom side adjacent to a top surface of said stack; and
depositing an electrolyte layer on said stack using a PVD process with said mask arranged having said bottom side adjacent to said film stack.

2. The method of claim 1, wherein said PVD process comprises RF sputtering.

3. The method of claim 1, wherein said electrolyte layer comprises LiPON.

4. The method of claim 1, wherein said electrode layer is a cathode layer.

5. The method of claim 4, wherein said cathode layer comprises LiCoO₂.

6. The method of claim 1, wherein said electrochemical devices are thin film batteries.

7. The method of claim 1, wherein said mask is a metal body with a layer of dielectric material on said top side.

8. The method of claim 7, wherein said metal body comprises invar.

9. The method of claim 7, wherein said dielectric material comprises one or more of silicon oxide and silicon nitride.

10. The method of claim 1, wherein said bottom side has an electrical conductivity in the range of 10⁵ to 10⁷ S/m.

11. The method of claim 1, wherein said top side has an electrical conductivity less than 10⁻⁷ S/m.

12. A system for manufacturing electrochemical devices comprising:
a shadow mask for patterning an electrolyte layer of an electrochemical device, said shadow mask comprising:
a planar body with top and bottom sides, said bottom side having an electrical conductivity in the range of 10⁵ to 10⁷ S/m and said top side having an electrical conductivity less than 10⁻⁷ S/m; and
a first system for depositing a device stack on a substrate comprising a current collector, an electrode layer, and said electrolyte layer, said first system comprising a PVD deposition tool configured for depositing said electrolyte with said shadow mask with said bottom side of said shadow mask facing said substrate during said depositing.

13. A shadow mask for patterning an electrolyte layer of an electrochemical device, said mask comprising:
a planar body with a top side and a bottom side, said bottom side having an electrical conductivity in the range of 10⁵ to 10⁷ S/m and said top side having a electrical conductivity less than 10⁻⁷ S/m.

14. The shadow mask of claim 13, wherein said planar body is a metal body with a layer of dielectric material on said top side.

15. The shadow mask of claim 14, wherein said dielectric material comprises one or more of silicon oxide and silicon nitride.
